(19) United States
(12) Patent Application Publication
(10) Pub. No.: US 2007/0132005 A1
(43) Pub. Date: Jun. 14, 2007

(54) Electrically Erasable and Programmable Read Only Memories Including Variable Width Overlap Regions and Methods of Fabricating the Same

(75) Inventors: Young-Ho Kim, Hwascong-si (KR); Yong-Tae Kim, Yongin-si (KR); Weon-Ho Park, Suwon-si (KR); Kyoung-Hwan Kim, Hwascong-si (KR); Ji-Hoon Park, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/562,223

(22) Filed: Nov. 21, 2006

(30) Foreign Application Priority Data
Dec. 9, 2005 (KR) 10-2005-0120606

(51) Int. Cl. H01L 21/336

(52) U.S. Cl. 257/315; 438/257

(57) ABSTRACT

An electrically erasable and programmable read only memory (EEPROM) is fabricated by forming isolation patterns defining active regions in predetermined regions of a semiconductor substrate including a memory transistor region and a selection transistor region. A gate insulating layer having tunnel regions is formed on the active regions. A first conductive layer is formed on the resultant structure having the gate insulating layer. The first conductive layer is patterned to form openings exposing top surfaces of the isolation patterns. The patterning takes place such that a distance between a selected opening and the active region adjacent the opening varies depending on the width of the isolation pattern disposed under the opening. Related EEPROM devices are also disclosed.

### CROSS-REFERENCE TO RELATED PATENT APPLICATION

This application claims the benefit under 35 USC §119 of Korean Patent Application No. 10-2005-0120606, filed on Dec. 9, 2005, the disclosure of which is hereby incorporated by reference in its entirety as if set forth fully herein.

### FIELD OF THE INVENTION

The present invention relates to integrated circuit memory devices and methods of fabricating the same, and more particularly, to electrically erasable and programmable read only memory (EEPROM) devices and methods of fabricating the same.

### BACKGROUND OF THE INVENTION

An EEPROM is a kind of nonvolatile memory device that retains stored data in the absence of a power supply voltage and can electrically change the stored data. The EEPROM may be generally categorized as a flash memory device or a floating gate tunnel oxide (FLOTOX) type memory device. A unit memory cell of an EEPROM may include a memory transistor for storing data and a selection transistor for controlling access to the memory transistor.

With an increase in the integration density of FLOTOX and/or other types of EEPROMs, technical problems may occur. For example, differences in physical, optical, and chemical effects caused by a difference in pattern density may make the electrical characteristics of memory cells nonuniform. Hereinafter, technical problems due to the difference in pattern density will be further described with reference to FIGS. 1A through 1D.

FIG. 1A is a plan view of a portion of a cell array of a conventional EEPROM, and FIGS. 1B through 1D are cross sectional views taken along dotted lines I-I′, II-II′, and III-III′ of FIG. 1A, respectively.

Referring to FIGS. 1A through 1D, isolation patterns 20 are disposed in predetermined regions of a semiconductor substrate 10 to define active regions ACT. The semiconductor substrate 10 includes a cell array region CAR and a peripheral circuit region. Also, the cell array region CAR includes a memory transistor region MTR where memory transistors are disposed and a selection transistor region STR where selection transistors are disposed.

Gate patterns are disposed on the active regions ACT across the isolation patterns 20. The gate patterns include a first conductive pattern 51, an inter-gate dielectric pattern 52, and a second conductive pattern 53 that are stacked sequentially. Also, the gate patterns include memory gate patterns MG disposed in the memory transistor region MTR and selection gate patterns SG disposed in the selection transistor region STR.

The first conductive pattern 51 of the memory gate pattern MG is electrically isolated from its adjacent conductive patterns because it is used as a floating gate pattern for storing data. In order to provide effective insulation, the first conductive pattern 51 of the memory gate pattern MG is spatially separated from its adjacent conductive patterns by openings 40 exposing top surfaces of the isolation patterns 20 as shown in FIG. 1A. As a result, the memory gate pattern MG includes a plurality of isolated first conductive patterns 51, which are covered with the inter-gate dielectric pattern 52. By comparison, the selection gate pattern SG includes only one first conductive pattern 51, which crosses over the isolation patterns 20.

A gate insulating layer 30 is disposed under the gate patterns. The gate insulating layer 30 disposed under the memory gate pattern MG includes a tunnel region TR with a relatively small thickness. In a write operation, a tunneling phenomenon arises in the tunnel region TR so that electric charge is injected into the floating gate patterns. Since the amount of electric charge injected into the floating gate pattern affects a channel electric potential of the memory transistor, it determines data stored in the memory transistor.

A tunnel impurity region 60T is provided under the tunnel region TR, and impurity regions 60SD used for source and drain electrodes of the memory and selection transistors are provided in the active region ACT on both sides of the gate pattern. A halo region (not shown), generally of a conductivity type different from the impurity region 60SD, may also be provided on one side of the impurity region 60SD. The halo region is typically formed to reduce or prevent the occurrence of punch-through in transistors disposed in the peripheral circuit region, but it also may be formed in the cell array region CAR. The impurity region 60SD and the halo region may be obtained through an ion implantation process 90 using the gate patterns as an ion implantation mask.

The formation of the isolation patterns 20 includes anisotropically etching the semiconductor substrate 10 to form trenches 15 and forming an insulating layer to fill the trenches 15. In this case, sidewalls of the trenches 15 may have different inclinations owing to differences in physical and chemical effects caused by a difference in pattern density (i.e., a loading effect). For example, the sidewall of the trench 15 may have a greater inclination in a region where the isolation pattern 20 is wide (hereinafter, an outer region OR) than in a region where the isolation pattern 20 is narrow (hereinafter, an inner region IR) (i.e., θ₁>θ₂). As the sidewall of the trench 15 in the outer region OR has a greater inclination, the length of a path through which impurities are implanted into the active region ACT during the ion implantation process for forming the impurity region 60SD and the halo region decreases, which may result in variations in the electrical characteristics of the cells.

Moreover, the formation of the first conductive pattern 51 includes an opening forming operation of forming a first conductive layer to cover the active region ACT and patterning the first conductive layer to form the openings 40 exposing the top surfaces of the isolation patterns 20 and a gate patterning operation of patterning the first conductive layer having the openings 40 again. However, since the gate patterning operation is performed by etching the isolation patterns 20 exposed by the openings 40, groove regions 25 may be formed as shown in FIG. 1D. The groove regions 25 may further decrease lengths d1 and d2 of paths through which the impurities diffuse, which may exacerbate the variations in the electrical characteristics of the cells.

FIG. 2 is a graph showing a variation in the electrical characteristic of EEPROM cells caused by the diffusion of impurities.

Referring to FIG. 2, operating voltages of EEPROM cells fabricated according to a conventional technique were measured. When operating voltages Lvcc of 8 cells connected to one word line were measured (refer to D1), the average of the operating voltages Lvcc was 1.544 V. By comparison, when operating voltages Lvcc of 7 cells other than a cell adjacent to the outer region OR (hereinafter, an edge cell) were measured (refer to D2), the average of the operating voltages Lvcc was 1.456 V. As a result, it can be seen that the edge cell may be very different from the other cells in an operating voltage characteristic. Considering a structural difference between the edge cell and the other cells, a variation in the electrical characteristic of the edge cell may come from the diffusion of impurities, which may be due to the above-described difference in the inclination of the sidewall of the trench 15 caused by the difference in pattern density, and also may be due to the decrease in the length of the path through which the impurities diffuse owing to the groove region 25.

### SUMMARY OF THE INVENTION

According to some embodiments of the present invention, methods of fabricating EEPROM devices include forming isolation patterns defining active regions in a substrate, including a memory transistor region and a selection transistor region. A gate insulating layer is formed on the active regions. A first conductive layer is formed on the substrate including on the gate insulating layer. The first conductive layer is patterned to form openings that expose surfaces of the isolation patterns. For example, at least some of the top surfaces of the isolation patterns may be exposed. The patterning is performed such that a distance between a selected opening and the active region adjacent the opening varies depending on a width of the isolation pattern adjacent the opening.

The active regions may include outer active regions and inner active regions interposed between the outer active regions. In some embodiments of the present invention, the outer active region may be wider in the selection transistor region than in the memory transistor region, while the inner active region may be of same width in the memory transistor region and the selection transistor region.

According to other embodiments of the present invention, after forming the openings, an inter-gate dielectric layer and a second conductive layer may be sequentially formed on the substrate, including on the openings. Subsequently, the second conductive layer, the inter-gate dielectric layer, and the first conductive layer may be patterned to form gate patterns crossing over the active regions.

The gate patterns may include memory gate patterns disposed in the memory transistor region and selection gate patterns disposed in the selection transistor region. In some embodiments, the openings may be formed on the isolation patterns in the memory transistor region, and the memory gate patterns may be formed across the openings and the active regions.

The openings may include outer openings disposed adjacent ends of the memory gate patterns and inner openings interposed between the outer openings. In some embodiments of the present invention, the first conductive layer is patterned such that a distance between a selected outer opening and the active region adjacent the selected outer opening is greater than a distance between a selected inner opening and the active region adjacent the selected inner opening.

According to other embodiments of the present invention, the forming of the gate insulating layer may include forming a first gate insulating layer on the active regions (for example, at least part of the tops thereof); patterning the first gate insulating layer to form tunnel regions exposing the active regions; and forming a second gate insulating layer on the exposed surfaces of the active regions. In this case, tunnel regions may be disposed in the memory transistor region.

The forming of the first gate insulating layer may include forming a silicon oxide layer through a thermal oxidation process, and the forming of the second gate insulating layer may include performing a thermal process using oxygen and/or nitrogen to form a silicon oxide layer and/or a silicon oxynitride layer on the surfaces of the active regions exposed by the tunnel regions.

According to other embodiments of the present invention, an EEPROM includes isolation patterns disposed in a substrate including a memory transistor region and a selection transistor region to define active regions. A memory gate pattern and a selection gate pattern are disposed in the memory transistor region and in the selection transistor region, respectively. The memory gate pattern and the selection gate pattern each include a first conductive pattern disposed on the active region. A gate insulating layer is interposed between the memory and selection gate patterns and the active regions. The first conductive pattern of the memory gate pattern includes a plurality of floating gate patterns that are isolated from one another and disposed on the active regions, and the width of a region where the floating gate pattern overlaps the isolation patterns disposed on sides of the floating gate pattern varies depending on the width of the isolation patterns.

In some embodiments of the present invention, the floating gate patterns may include outer floating gate patterns disposed on both sides of the memory gate pattern, and inner floating gate patterns interposed between the outer floating gate patterns. In these embodiments, the width of a region where a selected outer floating gate pattern overlaps the isolation pattern on one side of the outer floating gate pattern may be different from the width of a region where the outer floating gate pattern overlaps the isolation pattern on the other side of the outer floating gate pattern.

In other embodiments of the present invention, the outer floating gate pattern may include an inner overlap region where the outer floating gate pattern overlaps the isolation pattern adjacent the inner floating gate pattern, and an outer overlap region where the outer floating gate pattern overlaps the isolation pattern spaced apart (i.e., remote) from the inner floating gate pattern. In these embodiments, the outer overlap region may be wider than the inner overlap region. The region where the inner floating gate pattern overlaps the isolation pattern on one side of the inner floating gate pattern may be of same width as a region where the inner floating gate pattern overlaps the isolation pattern on the other side of the inner floating gate pattern.

The active regions may include outer active regions disposed adjacent both ends of the memory gate pattern, and inner active regions interposed between the outer active regions. In these embodiments, the outer active region may be wider in the selection transistor region than in the memory transistor region. In contrast, the inner active region may be of same width in both the memory transistor region and the selection transistor region.

The memory gate pattern and the selection gate pattern may each include an inter-gate dielectric pattern and a second conductive pattern that are sequentially stacked on the first conductive pattern. In these embodiments, the first conductive pattern of the selection gate pattern may isolate the inter-gate dielectric pattern from the isolation pattern.

In some embodiments of the present invention, the gate insulating layer may include a tunnel region disposed in the active region of the memory transistor region, wherein the gate insulating layer in the tunnel region may be thinner than the gate insulating layer outside the tunnel region. In this case, the gate insulating layer may comprise a silicon oxide layer and/or a silicon oxynitride layer.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1A is a plan view of a portion of a cell array of a conventional electrically erasable and programmable read only memory (EEPROM);

FIGS. 1B through 1D are cross sectional views taken along dotted lines I-I′, II-II′, and III-III′ of FIG. 1A, respectively;

FIG. 2 is a graph showing the influence of pattern density on the electrical characteristics of conventional EEPROM cells;

FIGS. 3A through 6A are plan views of a portion of a cell array region, which illustrate methods of fabricating an EEPROM device according to various embodiments of the present invention and an EEPROM device so fabricated;

FIGS. 3B through 6B are cross sectional views taken along dotted lines I-I′ of FIGS. 3A through 6A, respectively;

FIGS. 3C through 6C are cross sectional views taken along dotted lines II-II′of FIGS. 3A through 6A, respectively; and

FIG. 7 is a plan view of an EEPROM according to embodiments of the present invention.

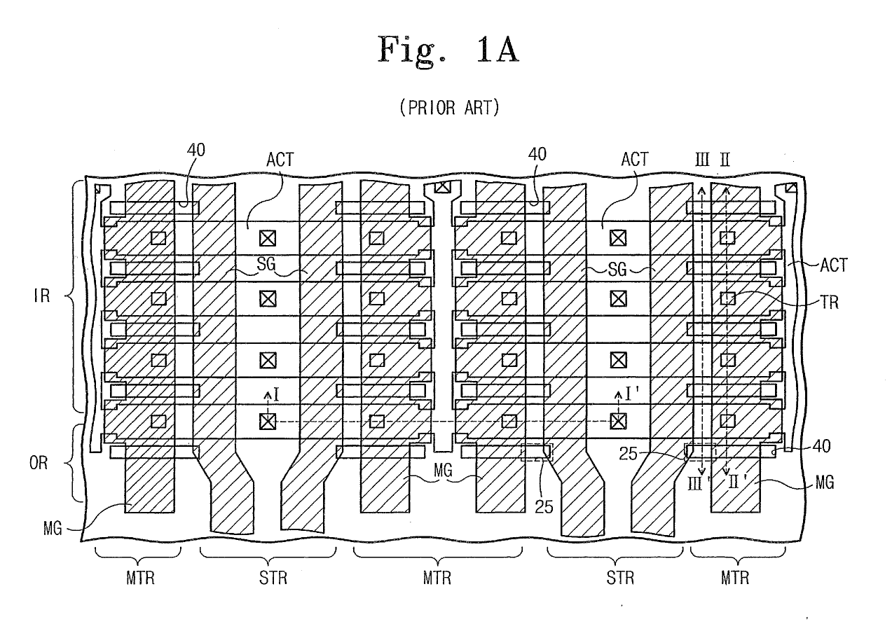

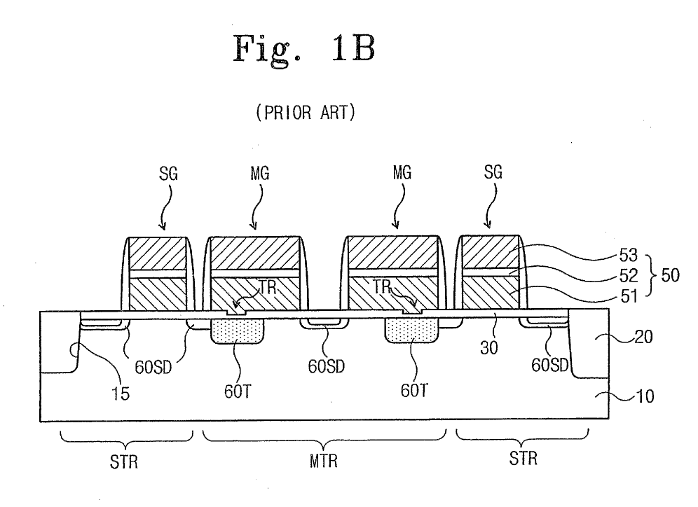

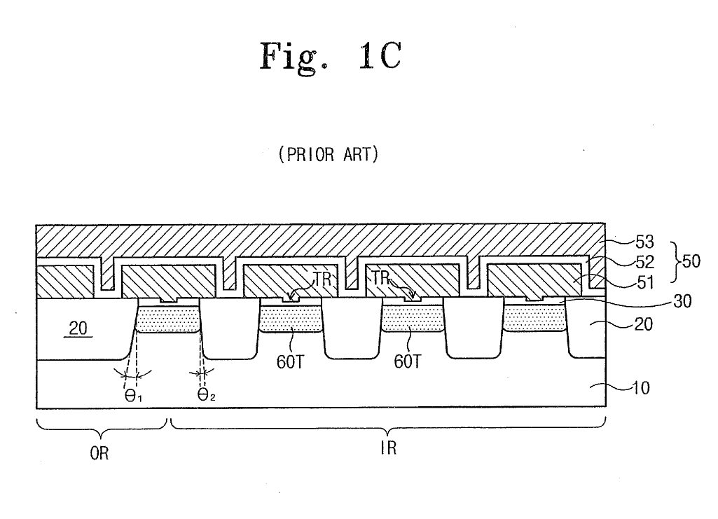

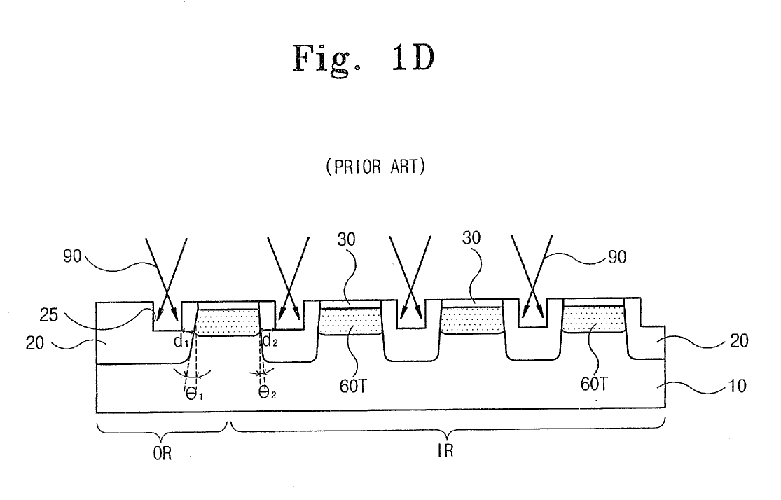

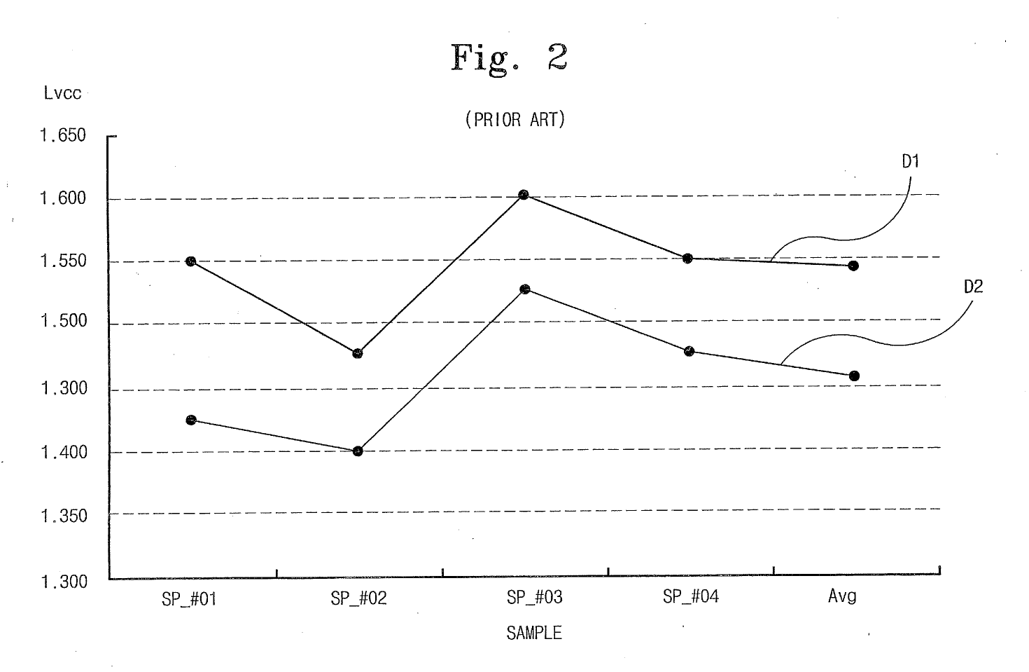

### DETAILED DESCRIPTION OF THE INVENTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “below”, “lower”, “above”,“upper”, “top”, “bottom” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly. Moreover, the term “beneath” also indicates a relationship of one layer or region to another layer or region relative to the substrate, as illustrated in the figures.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

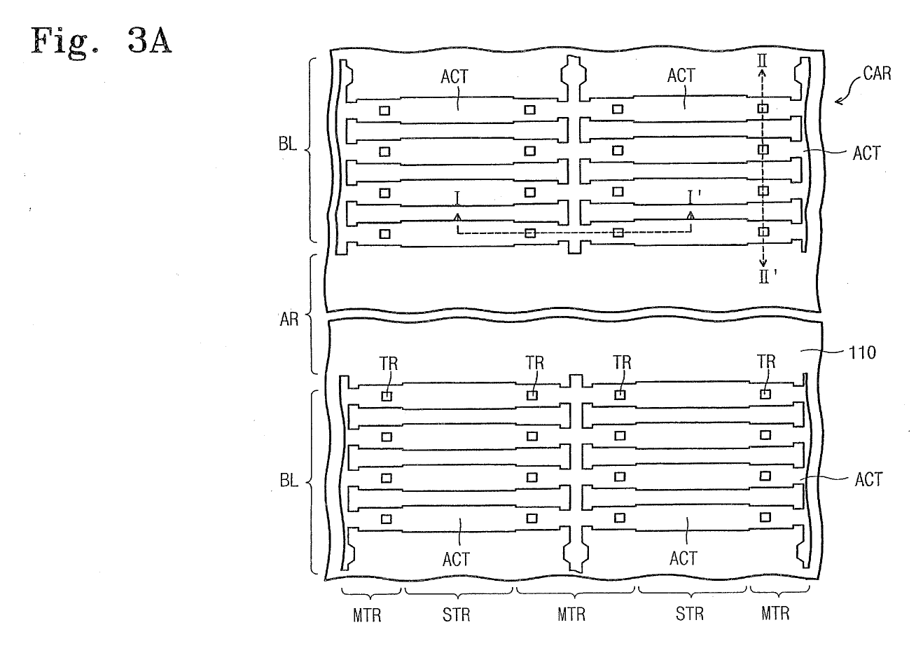

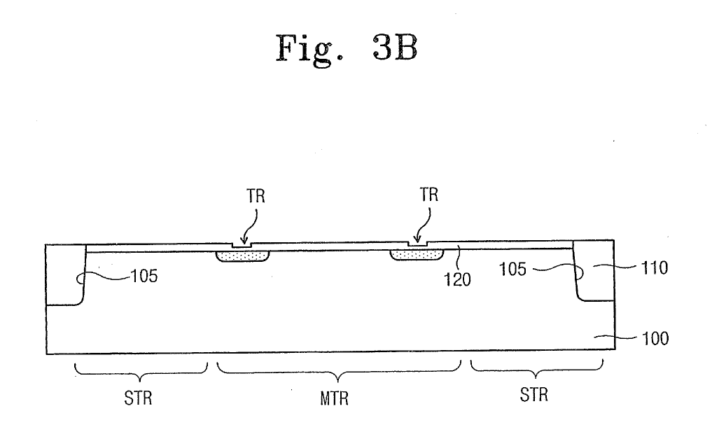

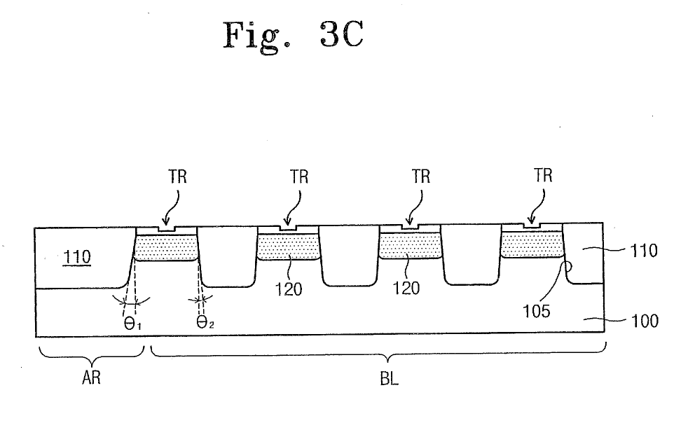

FIGS. 3A through 6A are plan views of a portion of a cell array region, which illustrate methods of fabricating EEPROM devices according to some embodiments of the present invention. FIGS. 3B through 6B are cross sectional views taken along dotted lines I-I′ of FIGS. 3A through 6A, respectively, and FIGS. 3C through 6C are cross sectional views taken along dotted lines II-II′ of FIGS. 3A through 6A, respectively.

Referring to FIGS. 3A through 3C, isolation patterns 110 are formed in predetermined regions of a substrate such as a semiconductor substrate 100 to define active regions ACT. The semiconductor substrate 100 may comprise a single element and/or compound semiconductor substrate, such as a monocrystalline silicon substrate, and may include one or more epitaxial and/or other conductive/insulating layers thereon. The semiconductor substrate 100 includes a cell array region CAR and a peripheral circuit region. The cell array region CAR includes a memory transistor region MTR where memory transistors for storing data are disposed and a selection transistor region STR where selection transistors for controlling access to the memory transistors are disposed.

The isolation patterns 110 may be formed using a shallow trench isolation (STI) technique. More specifically, the formation of the isolation patterns 110 may include forming trenches 105 to define the active regions ACT and forming an insulating layer to fill the trenches 105. In this case, the formation of the trenches 105 includes forming a trench mask pattern (not shown) to define the active regions ACT and anisotropically etching the semiconductor substrate 100 using the trench mask pattern as an etch mask. Afterwards, the insulating layer is etched until the top of the trench mask pattern is exposed, thereby completing the isolation pattern 110. Then, the trench mask pattern is removed to expose the active region ACT.

However, as described above, sidewalls of the trenches 105 may have different inclinations due to differences in physical and chemical effects caused by a difference in pattern density (i.e., a loading effect). For example, the sidewall of the trench 105 or the isolation pattern 110 may have a greater inclination in a region where the trench 105 is wide than in a region where the trench 105 is narrow. According to some embodiments of the present invention, as the cell array region CAR is comprised of a plurality of cells, the cell array region CAR includes a plurality of blocks BL separated by the isolation patterns 110. In this case, since an auxiliary region AR, such as a region for connecting interconnection lines (e.g., a gate contact region), is located between the blocks BL, the isolation pattern 110 formed in the auxiliary region AR is wider than that of the isolation pattern 110 formed in each of the blocks BL. As a result, an inclination θ₁ of the sidewall of the isolation pattern 110 formed in the auxiliary region AR is greater than an inclination θ₂ of the sidewall of the isolation pattern 110 formed in the block BL (i.e., θ₁>θ₂).

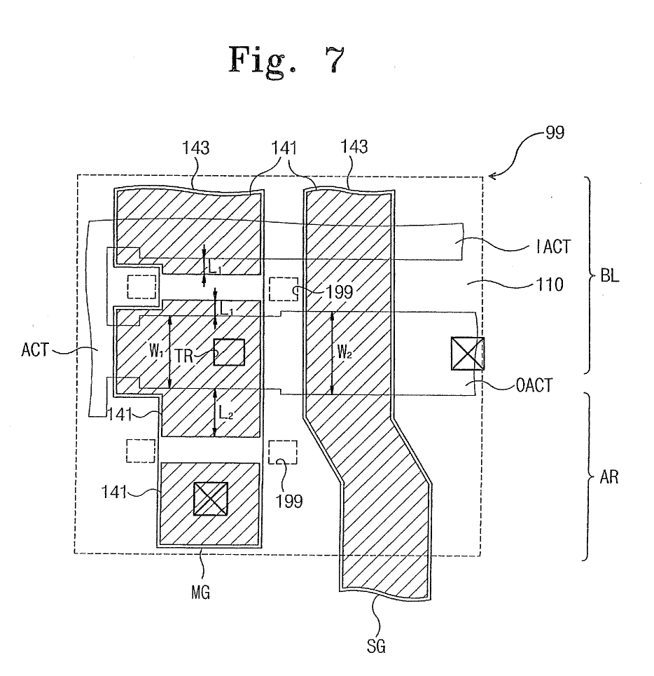

According to some embodiments of the present invention, the active region ACT adjacent the auxiliary region AR (hereinafter, an outer active region) is wider in the selection transistor region ST than in the memory transistor region MTR. As compared with the outer active region, the active region ACT spaced apart from (i.e., remote from) the auxiliary region AR and disposed in the block BL (hereinafter, an inner active region) may have the same width in both the memory transistor region MTR and the selection transistor region STR. (See FIG. 7.) The dependence of the variable width of the active region ACT on a distance from the auxiliary region AR can increase the uniformity of the electrical characteristics of the cells as will be described in more detail below.

A gate insulating layer 120 is formed on the resultant structure having the active region ACT. The formation of the gate insulating layer 120 includes forming a first gate insulating layer on the active region ACT, patterning the first gate insulating layer to form a tunnel region TR exposing the active region ACT, for example exposing at least some of a top surface of the active region ACT, and forming a second gate insulating layer on the active region ACT exposed by the tunnel region TR. The tunnel region TR is provided in the memory transistor region MTR and has an area smaller than the area of a region where the memory transistor region MTR overlaps the active region ACT.

The first gate insulating layer may be obtained by thermally oxidizing the active region ACT. Thus, the first gate insulating layer may be formed of a silicon oxide layer. The formation of the second gate insulating layer may include sequentially forming a silicon oxide layer and a silicon oxynitride layer on the active region ACT exposed by the tunnel region TR. In other embodiments, a silicon oxide layer or a silicon oxynitride layer may be formed. The silicon oxide layer for the second gate insulating layer may be obtained through a thermal oxidation process, and the silicon oxynitride layer for the second gate insulating layer may be obtained through a thermal oxidation process using process gases containing O₂ and N₂. Since the second gate insulating layer is formed through the thermal oxidation process, that the second gate insulating layer may also be formed on the remaining first gate insulating layer outside the tunnel region TR.

When the gate insulating layer 120 is formed as described above, the gate insulating layer 120 may be thinner in the tunnel region TR than outside the tunnel region TR as shown in FIG. 3B. The gate insulating layer 120 in the tunnel region TR is formed to a small thickness of about 10 Å to about 100 Å such that a tunneling phenomenon can occur effectively under desired voltage conditions for a write operation of the EEPROM.

Furthermore, before forming the second gate insulating layer, a predetermined ion implantation process may be carried out to form tunnel impurity regions 210. The ion implantation process may be performed using a predetermined ion implantation mask such that the tunnel impurity regions 210 are provided under the tunnel regions TR in the active region ACT. The ion implantation mask may be the same as the etch mask used to define the tunnel region TR, but the two masks may be different. Also, the tunnel impurity region 210 may be formed to a conductivity type different from the semiconductor substrate 100.

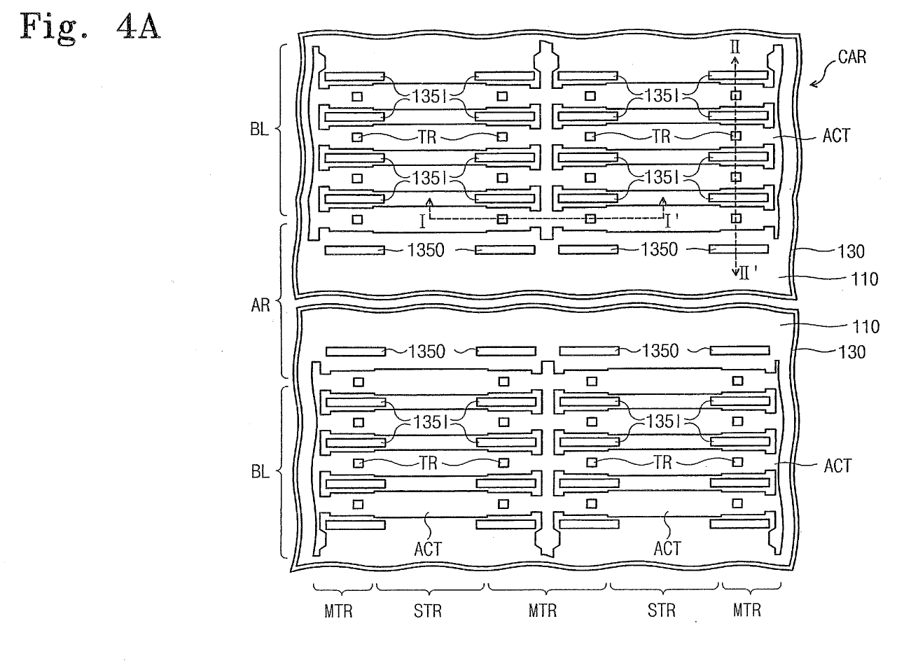

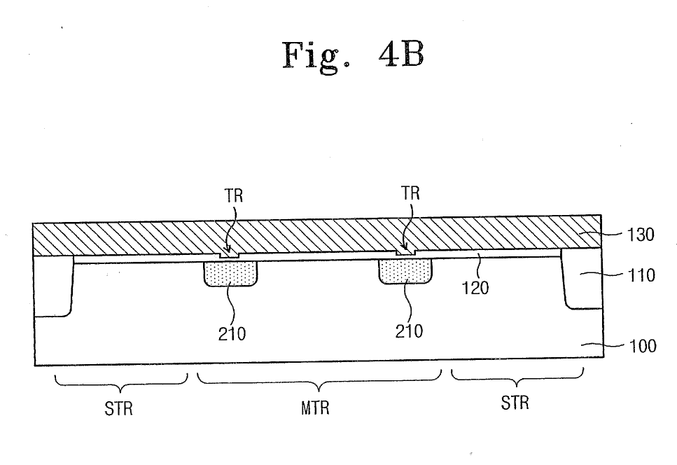

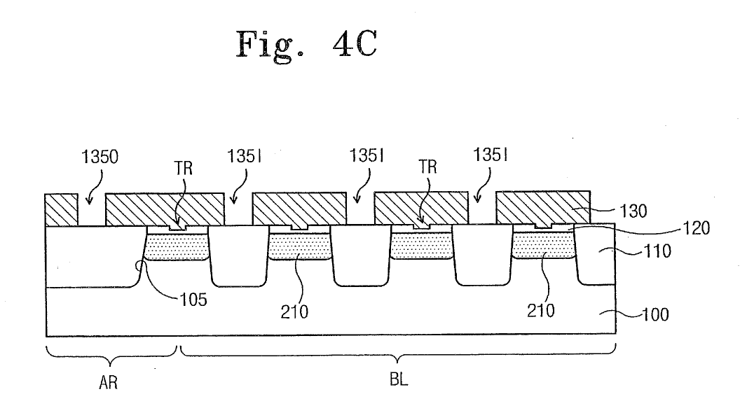

Referring to FIGS. 4A through 4C, a first conductive layer 130 is formed on the resultant structure having the gate insulating layer 120. The first conductive layer 130 may be a polycrystalline silicon (poly-Si) layer obtained through a deposition process. The first conductive layer 130 is used to form a floating gate electrode for the memory transistor and a gate electrode for the selection transistor in subsequent processes. As is well known, the floating gate electrode is an electrically isolated conductive pattern, which stores electric charges injected through the tunnel region TR.

Thereafter, the first conductive layer 130 is patterned, thereby forming openings 1350 and 1351 exposing surfaces, such as at least a portion of top surfaces, of the isolation patterns 110 in the memory transistor region MTR. The openings 1350 and 1351 are provided to electrically isolate the floating gate electrode. More specifically, in order to provide the electrical isolation of the gate electrode, the first conductive layer 130 having the openings 1350 and 1351 are patterned across the isolation patterns 110 during a subsequent gate patterning process.

The openings 1350 and 1351 may be divided into outer openings 1350 and inner openings 1351 according to locations. The outer openings 1350 are disposed on the isolation patterns 110 in the auxiliary region AR, while the inner openings 1351 are disposed on the isolation patterns 110 in the blocks BL. According to some embodiments of the present invention, a distance between the outer opening 1350 and its adjacent active region ACT (i.e., the outer active region) is greater than a distance between the inner opening 1351 and its adjacent active region ACT (i.e., the inner active region).

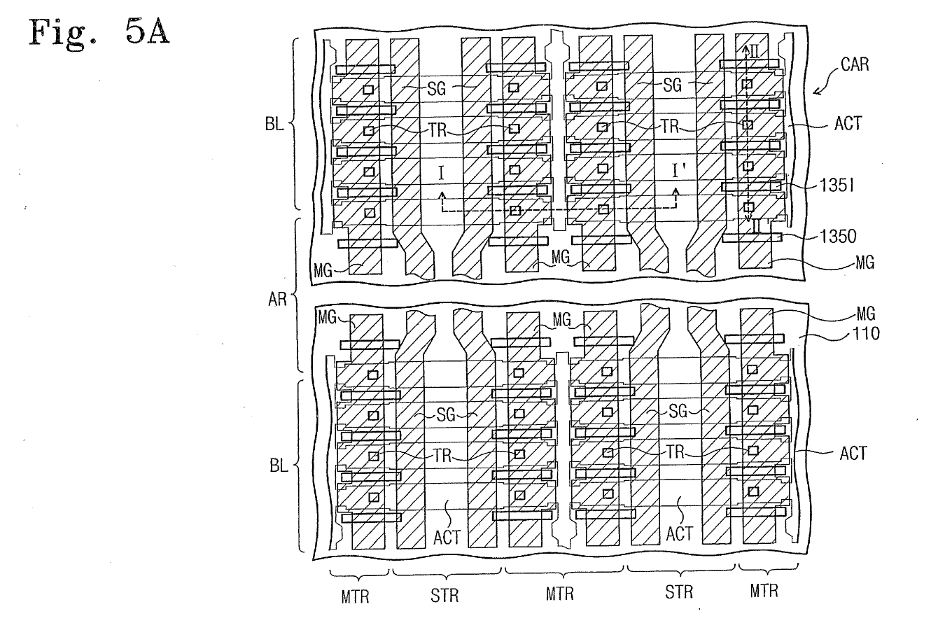

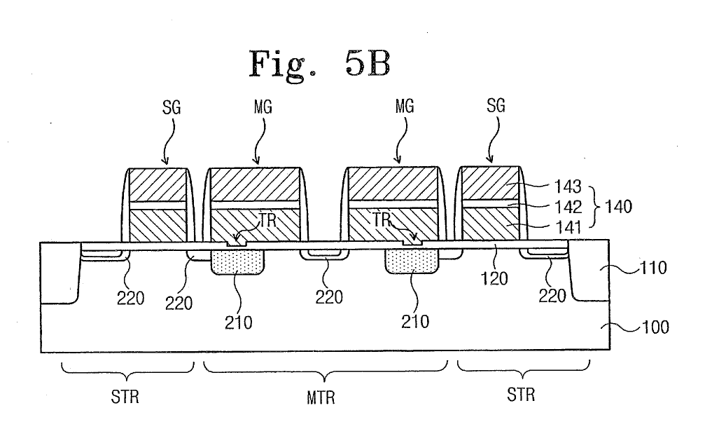

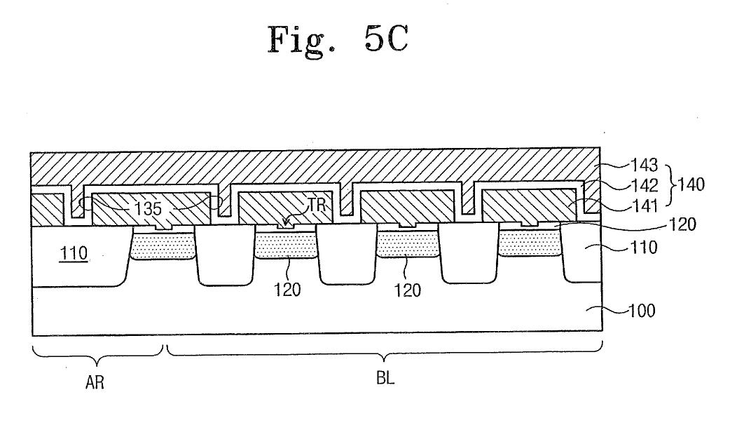

A relatively large distance between the outer opening 1350 and the outer active region can enhance the uniformity of the electrical characteristics of the cells, which is related to the inclination of the sidewall of the trench 105. This effect will be explained in more detail with reference to FIGS. 5A through 5C.

Referring to FIGS. 5A through 5C, an inter-gate dielectric layer and a second conductive layer are sequentially formed on the resultant structure having the openings 1350 and 1351. The inter-gale dielectric layer may be formed of a silicon oxide layer and/or a silicon oxynitride layer. For instance, the inter-gate dielectric layer may include a silicon oxide layer, a silicon nitride layer, and a silicon oxide layer that are stacked in sequence. The second conductive layer may be a conductive material layer including a poly-Si layer. For instance, the second conductive layer may include a poly-Si layer and a tungsten silicide layer that are stacked in sequence.

Subsequently, the second conductive layer, the inter-gate dielectric layer, and the first conductive layer 130 are sequentially patterned, thereby forming gate patterns, each of which includes a first conductive pattern 141, an inter-gate dielectric pattern 142, and a second conductive pattern 143 that are stacked sequentially. In this case, the gate patterns are provided across the isolation patterns 110.

The gate patterns may be classified into memory gate patterns MG and selection gate patterns SG. The memory gate patterns MG are disposed in the memory transistor region MTR, while the selection gate patterns SG are disposed in the selection transistor region STR. The memory gate patterns MG are formed across the openings 1350 and 1351 orthogonal to the active region ACT. Thus, the first conductive pattern 141 of the memory gate pattern MG is electrically isolated and serves as the floating gate electrode for storing data as stated above. In this case, since the tunnel region TR is formed in the memory transistor region MTR, the memory gate pattern MG in the memory transistor region MTR is located on the tunnel region TR.

Unlike the memory gate pattern MG, the first conductive pattern 141 of the selection gate pattern SG is not isolated by the openings 1350 and 1351 but crosses over the active regions ACT and the isolation patterns 110. In other words, the first conductive pattern 141 of the selection gate pattern SG separates the isolation pattern 110 from the inter-gate dielectric pattern 142. Thus, the first conductive pattern 141 of the selection gate pattern SG serves as the gate electrode for the selection transistor. In some embodiments of the present invention, the first and second conductive patterns 141 and 143 of the selection gate pattern SG are electrically connected to each other in the auxiliary region AR. In other embodiments of the present invention, although not shown in the drawings, the inter-gate dielectric pattern 142 may be etched or at least partially removed to electrically connect the first and second conductive patterns 141 and 143.

Thereafter, ion implantation processes are implemented using the gate patterns as ion implantation masks, so that impurity regions 220 for source and drain electrodes of the memory and selection transistors are formed in the active regions ACT. The impurity regions 220 may be formed to have a conductivity type different from the semiconductor substrate 100. During the formation of the impurity regions 220, a process of forming spacers on sidewalls of the gate patterns MG and SG may be further carried out. In addition, impurity ions may be implanted into the active regions ACT to form a halo region. As described above, the halo region may be provided to reduce or prevent the occurrence of punch-through in the transistors formed in the peripheral circuit region. Conventionally, impurities for the impurity regions 220 and the halo region diffuse into the active region ACT, which may result in a variation in the electrical characteristic of the cell. However, according to some embodiments of the present invention, the variation in the electrical characteristics of the cell caused by the diffusion of impurities can be reduced or minimized owing to the increased distance between the outer opening 1350 and the outer active region.

More specifically, the variations in the electrical characteristics of the cells may result from a combination of (1) the inclination of the sidewall of the outer active region affected by a difference in pattern density and/or (2) a reduction in the length of the path through which the impurities diffuse owing to the inclined sidewall of the outer active region. As described above, according to some embodiments of the invention, when a distance between the outer opening 1350 and the outer active region increases, the length of the path through which the impurities diffuse increases, which can reduce or minimize the variations in the electrical characteristics of the cells.

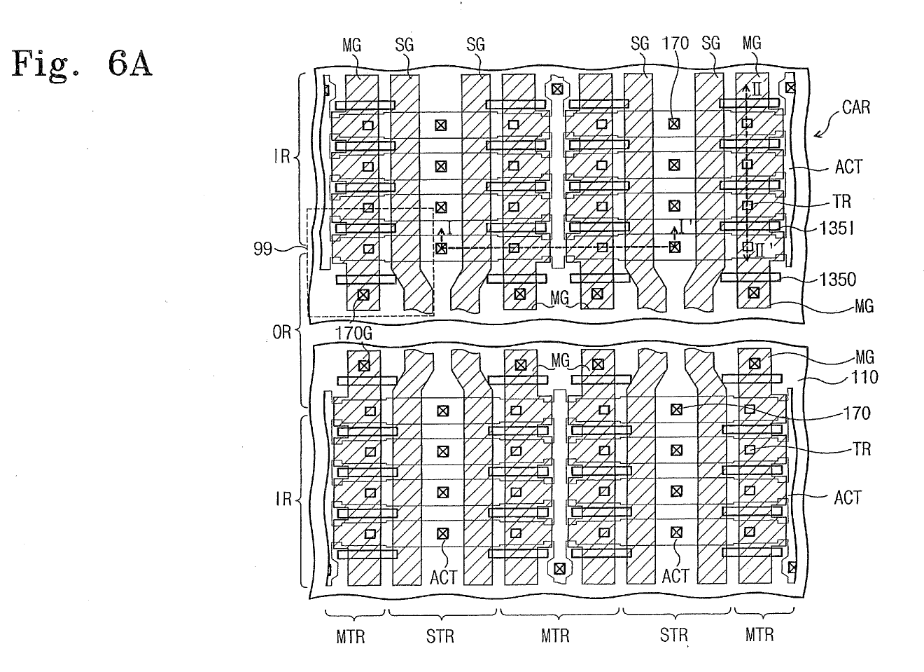

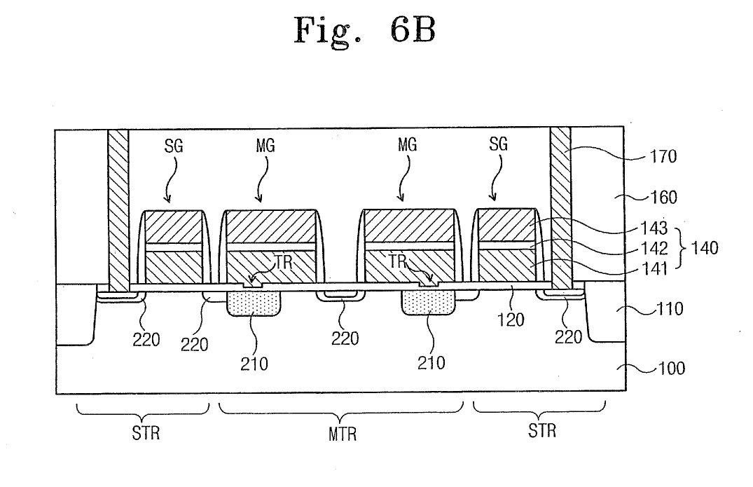

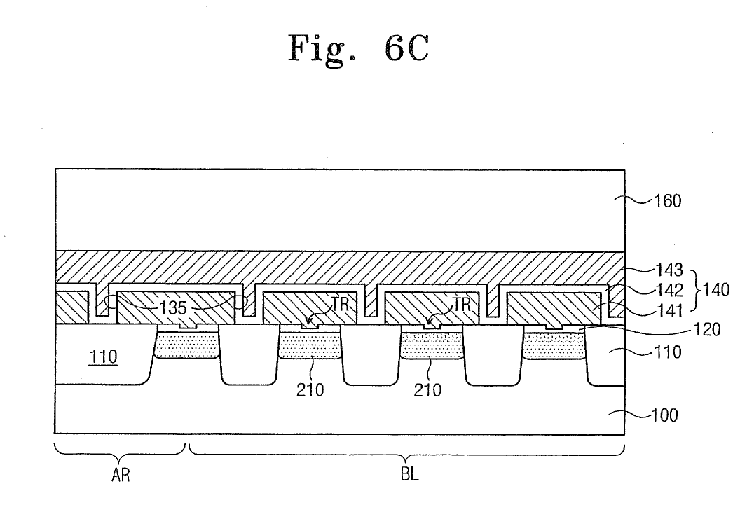

Referring to FIGS. 6A through 6C, an interlayer dielectric layer (ILD) 160 is formed on the resultant structure having the impurity region 220. The ILD 160 may be formed of an insulating material, such as silicon oxide. The ILD 160 is patterned to form contact holes 165 exposing the active region ACT in a predetermined region. The contact holes 165 may be formed to expose a top surface of the memory gate pattern MG and a top surface of the selection gate pattern SG. Afterwards, contact plugs 170 are formed to fill the contact holes 165 such that the contact plugs 170 are in contact with the impurity regions 220 or the gate patterns, respectively.

FIG. 7 is a plan view of an EEPROM according to some embodiments of the present invention. More specifically, FIG. 7 illustrates a portion 99 of the cell array region CAR shown in FIG. 6A.

Referring to FIGS. 6A through 6C and 7, an EEPROM according to these embodiments of the present invention includes isolation patterns 110, which are disposed in predetermined regions of a semiconductor substrate 100 to define active regions ACT. The semiconductor substrate 100 includes a cell array region CAR and a peripheral circuit region. The cell array region CAR includes blocks BL, each of which includes a plurality of cells, and an auxiliary region AR interposed between the blocks BL. Each of the cells includes a memory transistor region MTR where a memory transistor is disposed and a selection transistor region STR where a selection transistor is disposed.

The active regions ACT may be divided into outer active regions OACT and inner active regions IACT according to locations. The outer active regions OACT are disposed adjacent the auxiliary region AR, while the inner active regions IACT are disposed in the blocks BL. According to some embodiments of the present invention, the width of the inner active region IACT may be the same both in the memory transistor region MTR and the selection transistor region STR, but the width of the outer active region OACT may be different between the two regions MTR and STR. More specifically, the outer active region OACT is wider in the selection transistor region STR than in the memory transistor region MTR (i.e., W1<W2), as shown in FIG. 7. In this case, the width of the outer active region OACT may be equal to that of the inner active region IACT in the memory transistor region MTR. As a result, the width of the outer active region OACT is greater than that of the inner active region IACT in the selection transistor region STR.

Owing to this difference in width between the outer active region OACT and the inner active region IACT in the selection transistor region STR, the aforementioned differences in electrical characteristics between the cells can be reduced or minimized. More specifically, as described above, a selection transistor disposed in the outer active region OACT has a greater channel width than a selection transistor disposed in the inner active region IACT. In some embodiments of the present invention, by controlling a difference in the channel width, a difference in the electrical characteristics between the cells disposed in the outer and inner active regions, OACT and IACT, can be reduced or minimized.

Gate patterns MG and SG are disposed on the active regions ACT across the isolation patterns 110, and a gate insulating layer 120 is disposed between the gate patterns MG and SG and the active regions ACT. Each of the gate patterns MG and SG includes a first conductive pattern 141, an inter-gate dielectric pattern 142, and a second conductive pattern 143 that are stacked in sequence. In some embodiments, the first conductive pattern 141 is formed of a poly-Si layer, the inter-gate dielectric pattern 142 is formed of a silicon oxide layer and/or a silicon nitride layer, and the second conductive pattern 143 may be formed of at least one conductive layer of a poly-Si layer, a metal layer, and/or a silicide layer.

Impurity regions 220 are disposed between the gate patterns and used as source and drain electrodes of the memory and selection transistors. The impurity regions 220 may include lightly doped regions and heavily doped regions. In this case, the impurity regions 220 may have a double diffused drain (DDD) structure in which the heavily doped region is enclosed within the lightly doped region.

According to some embodiments of the present invention, the gate patterns may be classified into a memory gate pattern MG disposed in the memory transistor region MTR and a selection gate pattern ST disposed in the selection transistor region STR. The first conductive pattern 141 of the memory gate pattern MG includes a plurality of isolated portions, each of which is used as a floating gate electrode of the memory transistor. For this, the first conductive pattern 141 of the memory gate pattern MG not only is electrically isolated from conductive structures including the second conductive pattern 143, but also includes a sidewall exposing a surface of the isolation pattern 110.

According to some embodiments the present invention, a distance from the sidewall of the first conductive pattern 141 of the memory gate pattern MG to the active region ACT (hereinafter, an overlap width) is different on both sides of the outer active region OACT. More specifically, an overlap width L2 measured on one side of the outer active region OACT adjacent the auxiliary region AR is greater than an overlap width L1 measured on the other side of the outer active region OACT in the block BL (i.e., L2>L1). In contrast, the overlap width is the same on both sides of the inner active regions IACT. In this case, the overlap width measured on both sides of the inner active region IACT is equal to the overlap width L1 measured on the side of the outer active region OACT in the block BL.

This difference in the overlap width can lead to a reduced difference of electrical characteristics among the cells. Moreover, while the floating gate electrodes are being separated from one another, a recess region 199 with a bottom surface lower than the top surface of the active region ACT may be formed in the isolation pattern 110. The recess region 199 may form a path through which impurities diffuse into the active region ACT during the formation of the impurity regions 220. However, according to some embodiments of the present invention, by making the overlap widths measured on both sides of the outer active region OACT different (i.e., L1<L2), the variations in the electrical characteristics of the cells caused by the diffusion of impurities can be reduced.

Furthermore, according to some embodiments of the present invention, the floating gate electrode (i.e., the first conductive pattern 141 of the memory gate pattern MG) is wider on the outer active region OACT than on the inner active region IACT. An increase in the width of the floating gate electrode on the outer active region OACT can bring about an increase in coupling ratio between the second conductive pattern 143 and the floating gate electrode. According to one experimental example of the present invention, when a difference (i.e., L2-L1) between the overlap widths L1 and L2 was 0.15 μm, capacitance between the floating gate electrode and the second conductive pattern 143 increased to about 14%. Due to the increase in the capacitance, an operating voltage margin of the cell increased to about 0.05 V, so that the variations in the electric characteristics of the cells can be reduced.

According to some embodiments of the present invention, the gate insulating layer 120 includes a tunnel region TR with a small thickness. The tunnel region TR is disposed in the memory transistor region MTR and covered with the memory gate pattern MG. The gate insulating layer 120 is formed of a silicon oxide layer and/or a silicon nitride layer. In some embodiments, the tunnel region TR is formed of an insulating layer including a silicon nitride layer.

Thus, according to some embodiments of the present invention as described herein, a distance from a selected opening for separating the floating gate electrodes to the active region adjacent to the opening varies depending on the width of the isolation pattern disposed under the opening. For example, a distance between the opening and the active region is greater in the auxiliary region between the blocks than in the block comprised of a plurality of cells. In other words, by varying the distance between the opening and the active region according to the location of the opening, diffusion of impurities into the outer active region can be reduced or minimized during a subsequent impurity implantation process. Further, since the distance between the opening and the active region determines the width of the floating gate electrode, the cell coupling ratio of the EEPROM according to the present invention can increase. As the diffusion of impurities is reduced or prevented and the cell coupling ratio increases, a write margin of the EEPROM can improve and the dependence of the electrical characteristics of the cells upon location can be reduced or eliminated.

In addition, there may be a difference in the width of the active region between the memory transistor region and the selection transistor region. For example, the width of the outer active region adjacent the auxiliary region may be greater in the selection transistor region than in the memory transistor region, and the width of the inner active region spaced apart (i.e., remote) from the auxiliary region may be the same both in the memory transistor region and the selection transistor region. This variation in the width of the active region according to location can also reduce the dependence of the electrical characteristics of the cells upon location.

As a consequence, some embodiments of the present invention can provide an EEPROM in which a variation in pattern density according to location is reduced or minimized.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of fabricating an electrically erasable and programmable read only memory (EEPROM), comprising:
forming isolation patterns defining active regions in a substrate, including a memory transistor region and a selection transistor region;
forming a gate insulating layer on the active regions;
forming a conductive layer on the substrate including on the gate insulating layer; and
patterning the conductive layer to form openings that expose the isolation patterns, the patterning being performed such that a distance between a selected opening and the active region adjacent the opening varies depending on a width of the isolation pattern adjacent the opening.

2. The method of claim 1, wherein the active regions comprise outer active regions and inner active regions interposed between the outer active regions, and wherein the isolation patterns are formed such that the outer active region is wider in the selection transistor region than in the memory transistor region.

3. The method of claim 2, wherein the isolation patterns are further formed such that the inner active region is of same width in both the memory transistor region and the selection transistor region.

4. The method of claim 1, wherein the conductor layer is a first conductive layer and wherein patterning the first conductive layer is followed by:
sequentially forming an inter-gate dielectric layer and a second conductive layer on the substrate including on the openings; and
patterning the second conductive layer, the inter-gate dielectric layer, and the first conductive layer to form gate patterns crossing over the active regions.

5. The method of claim 4, wherein the gate patterns include memory gate patterns disposed in the memory transistor region and selection gate patterns disposed in the selection transistor region,
wherein the openings are formed on the isolation patterns in the memory transistor region,
and wherein the memory gate patterns are formed across the openings and the active regions.

6. The method of claim 5, wherein the openings comprise outer openings disposed adjacent ends of the memory gate patterns and inner openings interposed between the outer openings, and wherein the patterning the first conductive layer is performed such that a distance between a selected outer opening and the active region adjacent the outer opening is greater than a distance between a selected inner opening and the active region adjacent the inner opening.

7. The method of claim 1, wherein the forming of the gate insulating layer comprises:
forming a first gate insulating layer on the active regions;
patterning the first gate insulating layer to form tunnel regions exposing the active regions; and
forming a second gate insulating layer on the exposed surfaces of the active regions,
wherein tunnel regions are disposed in the memory transistor region.

8. The method of claim 7, wherein the forming of the first gate insulating layer comprises forming a silicon oxide layer through a thermal oxidation process,
and wherein the forming of the second gate insulating layer comprises performing a thermal process using oxygen and/or nitrogen to form a silicon oxide layer and/or a silicon oxynitride layer on the surfaces of the active regions exposed by the tunnel regions.

9. A method of fabricating an EEPROM, comprising:
forming isolation patterns defining active regions in a substrate including a memory transistor region and a selection transistor region, wherein the active regions comprise outer active regions and inner active regions interposed between the outer active regions;
forming a gate insulating layer on the active regions;
forming a first conductive layer on the substrate, including on the gate insulating layer; and
patterning the first conductive layer to form openings that expose the isolation patterns, the patterning being performed such that a selected outer active region is wider in the selection transistor region than in the memory transistor region.

10. The method of claim 9, wherein a selected inner active region is of same width in both the memory transistor region and the selection transistor region.

11. An EEPROM comprising:
isolation patterns disposed in a substrate including a memory transistor region and a selection transistor region to define active regions;
a memory gate pattern and a selection gate pattern disposed in the memory transistor region and in the selection transistor region, respectively, the memory gate pattern and the selection gate pattern each including a conductive pattern disposed on the active region; and
a gate insulating layer interposed between the memory and selection gate patterns and the active regions,
wherein the conductive pattern of the memory gate pattern includes a plurality of floating gate patterns that are isolated from one another and disposed on the active regions, and a width of a region where the floating gate pattern overlaps the isolation patterns disposed on sides of the floating gate pattern varies depending on the width of the isolation patterns.

12. The EEPROM of claim 11, wherein the floating gate patterns comprise:
outer floating gate patterns disposed on both sides of the memory gate pattern; and
inner floating gate patterns interposed between the outer floating gate patterns,
wherein a width of a region where a selected outer floating gate pattern overlaps the isolation pattern on a first side of the outer floating gate pattern is different from a width of a region where the outer floating gate pattern overlaps the isolation pattern on a second side of the outer floating gate pattern.

13. The EEPROM of claim 12, wherein the outer floating gate pattern comprises:
an inner overlap region where the outer floating gate pattern overlaps the isolation pattern adjacent the inner floating gate pattern; and
an outer overlap region where the outer floating gate pattern overlaps the isolation pattern spaced apart from the inner floating gate pattern,
wherein the outer overlap region is wider than the inner overlap region.

14. The EEPROM of claim 12, wherein a region where the inner floating gate pattern overlaps the isolation pattern on a first side of the inner floating gate pattern is of same width as a region where the inner floating gate pattern overlaps the isolation pattern on a second side of the inner floating gate pattern.

15. The EEPROM of claim 12, wherein the active regions comprise:
outer active regions disposed adjacent both ends of the memory gate pattern; and
inner active regions interposed between the outer active regions,
wherein the outer active region is wider in the selection transistor region than in the memory transistor region.

16. The EEPROM of claim 15, wherein the inner active region is of same width in both the memory transistor region and the selection transistor region.

17. The EEPROM of claim 11, wherein the conductive pattern is a first conductive pattern and wherein the memory gate pattern and the selection gate pattern each includes an inter-gate dielectric pattern and a second conductive pattern that are sequentially stacked on the first conductive pattern,
wherein the first conductive pattern of the selection gate pattern isolates the inter-gate dielectric pattern from the isolation pattern.

18. The EEPROM of claim 11, wherein the gate insulating layer includes a tunnel region disposed in the active region of the memory transistor region,
wherein the gate insulating layer in the tunnel region is thinner than the gate insulating layer outside the tunnel region.

19. The EEPROM of claim 18, wherein the gate insulating layer comprises a silicon oxide layer and/or a silicon oxynitride layer, and
wherein the gate insulating layer in the tunnel region comprises an insulating layer including a silicon oxynitride layer.

20. An EEPROM comprising:
isolation patterns disposed in a substrate including a memory transistor region and a selection transistor region to define active regions;
a memory gate pattern and a selection gate pattern disposed in the memory transistor region and in the selection transistor region, respectively; and
a gate insulating layer interposed between the memory and selection gate patterns and the active regions,
wherein the active regions comprise:
outer active regions disposed adjacent both ends of the memory gate pattern; and
inner active regions interposed between the outer active regions,
wherein an outer active region is wider in the selection transistor region than in the memory transistor region.

21. The EEPROM of claim 20, wherein an inner active region is of same width in both the memory transistor region and the selection transistor region.
